(19) United States
(12) Patent Application Publication
(10) Pub. No.: US 2026/0293419 A1
(43) Pub. Date: Sep. 24, 2026

(54) LIGHT-EMITTING ELEMENT AND DISPLAY DEVICE

(71) Applicant: Sharp Display Technology Corporation, Kameyama City, Mie (JP)

(72) Inventors: TAKAYUKI NAKA, Sakai City, Osaka (JP); Kazuki MARUHASHI, akai City, Osaka (JP); Yuki FUKUNARI, Sakai City, Osaka (JP)

(21) Appl. No.: 19/476,462

(22) PCT Filed: Apr. 19, 2023
(86) PCT No.: PCT/JP2023/015653

§ 371 Date: Oct. 17, 2025

(51) Int. Cl. H10K 50/115; H10K 50/15; H10K 102/00

(52) U.S. Cl. CPC H10K 50/115; H10K 50/15; H10K 2102/351

(57) ABSTRACT

A light-emitting element (10) includes a light-emitting layer (6) and a charge function layer (4). The charge function layer (4) includes an inorganic layer (4U) including an inorganic hole transport material, at least one void (4Z), and an organic molecule (T). The organic molecule (T) includes a first functional group (K1) capable of bonding to the inorganic hole transport material, and a second functional group (K2) having an electron-withdrawing property or an electron-donating property.

### TECHNICAL FIELD

The disclosure relates to a light-emitting element and the like.

### BACKGROUND ART

PTL 1 discloses a light-emitting element including a dipole layer between a hole transport layer and an active layer.

### CITATION LIST

### Patent Literature

PTL 1: US 2013/15424 A

### SUMMARY

### Technical Problem

Known light-emitting elements have a problem that a high drive voltage is required.

### Solution to Problem

A light-emitting element according to the disclosure includes an anode and a cathode, a light-emitting layer located between the anode and the cathode, and a charge function layer located between the anode and the light-emitting layer, wherein the charge function layer includes an inorganic layer including an inorganic hole transport material, at least one void, and an organic molecule, and the organic molecule includes a first functional group capable of bonding to the inorganic hole transport material and a second functional group having an electron-withdrawing property or an electron-donating property.

### Advantageous Effects of Disclosure

The drive voltage of the light-emitting element can be reduced.

### BRIEF DESCRIPTION OF DRAWINGS

FIG. 1 is a cross-sectional view illustrating a configuration example of a light-emitting element according to the disclosure.

FIG. 2 is a cross-sectional view illustrating a configuration example of part of a light-emitting element.

FIG. 3 is a band diagram of an inorganic hole transport material (p-type semiconductor) and a charge function layer.

FIG. 4 is a schematic diagram illustrating an example of an organic molecule.

FIG. 5 is a structural formula depicting an example of an organic molecule.

FIG. 6 is a flowchart illustrating an example of a method for manufacturing nanoparticles.

FIG. 7 is a flowchart illustrating an example of a method for manufacturing a light-emitting element.

FIG. 8 is a cross-sectional SEM image of a light-emitting element according to Example 1.

FIG. 9 is a cross-sectional SEM image of a light-emitting element according to Example 2.

FIG. 10 is a graph depicting voltage (V)-luminance (L) characteristics of light-emitting elements according to Example 1, Example 2, Comparative Example 1, and Comparative Example 2.

FIG. 11 is a graph depicting voltage (V)-current density (J) characteristics of light-emitting elements according to Example 1, Example 2, Comparative Example 1, and Comparative Example 2.

FIG. 12 is a flowchart illustrating an example of a method for manufacturing a light-emitting element.

FIG. 13A is a flowchart illustrating an example of a method for manufacturing a light-emitting element.

FIG. 13B is a cross-sectional view illustrating an example of a method for manufacturing a light-emitting element.

FIG. 14 is a schematic diagram illustrating a configuration example of a display device according to the present embodiment.

### DESCRIPTION OF EMBODIMENTS

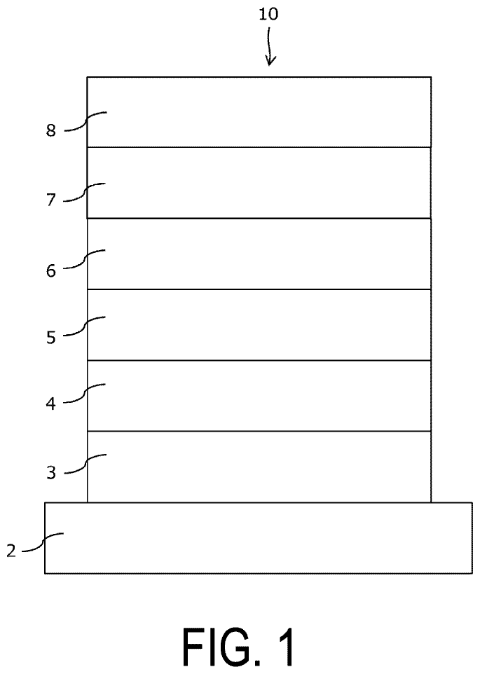

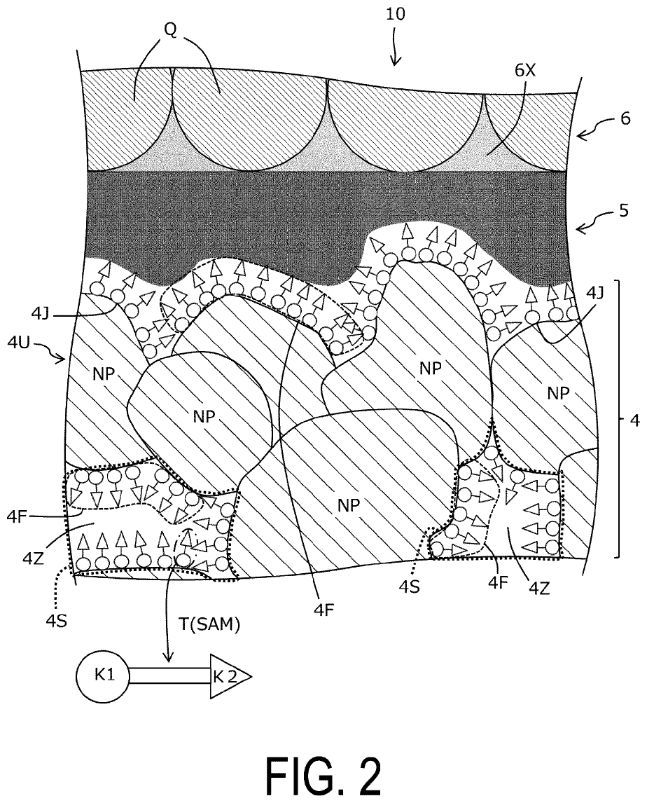

FIG. 1 is a cross-sectional view illustrating a configuration example of a light-emitting element according to the disclosure. FIG. 2 is a cross-sectional view illustrating a configuration example of part of a light-emitting element. As illustrated in FIG. 1, a light-emitting element 10 includes an anode 3, a charge function layer 4, a hole transport layer 5, a light-emitting layer 6, an electron transport layer 7, and a cathode 8 layered in this order from a lower layer side (a side of a pixel circuit substrate 2). The light-emitting layer 6 may be a quantum dot light-emitting layer including a plurality of quantum dots Q.

As illustrated in FIG. 2, the light-emitting element 10 includes the light-emitting layer 6 located between the anode 3 and the cathode 8, and the charge function layer 4 located between the anode 3 and the light-emitting layer 6. The charge function layer 4 includes an inorganic layer 4U including an inorganic hole transport material, one or more voids 4Z, and an organic molecule T. The organic molecule T includes a first functional group K1 capable of bonding to the inorganic hole transport material, and a second functional group K2 having an electron-withdrawing property or an electron-donating property. The void 4Z of the charge function layer 4 refers to a space where neither the inorganic hole transport material nor the organic molecule is present. A space 4S of the charge function layer 4 is a space where the inorganic hole transport material is not present. The void 4Z and the space 4S are located inside the charge function layer 4 and the inorganic layer 4U.

The organic molecule T may include the first functional group K1 including at least one of a carboxyl group, silanol group, phosphoryl group, thiol group, or amino group, and the second functional group K2 including at least one of a nitro group, halogen group, amino group, methoxy group, or ethoxy group.

In the charge function layer 4 of the light-emitting element 10, the organic molecules T enter into the space 4S, so that the carrier density and the mobility in the charge function layer 4 are increased, and the drive voltage of the light-emitting element 10 is lowered. The charge function layer 4 may be a hole injection layer (HIL).

The second functional group K2 in FIG. 2 may have an electron-withdrawing property, for example, when the inorganic hole transport material is a p-type semiconductor, and may have an electron-donating property (hole-withdrawing property) when the inorganic hole transport material is an n-type semiconductor.

As illustrated in FIG. 2, the organic molecule T may be arranged in the space 4S to be in contact with the void 4Z. The organic molecule T is a self-assembled monomolecule, and an organic film 4F (self-assembled monomolecular film) including the self-assembled monomolecule may be arranged in the space 4S to be in contact with the void 4Z. The organic film 4F may be arranged on an edge of the space 4S. The void 4Z may be located inside the inorganic layer 4U.

The porosity in the charge function layer 4 may be from 3.0% to 15.0%. The porosity may be a ratio of a void area to a cross-sectional area in a cross section of the charge function layer 4. When the porosity is less than 3%, there is a possibility that sufficient organic molecules T are not present in the charge function layer 4, so that the effect of an improvement in carrier density is small. On the other hand, when the porosity is more than 15%, the effect of the improvement in carrier density is saturated, so that there is a possibility that carrier transport capability of the charge function layer 4 is reduced due to a small rate of the inorganic hole transport material.

An average size of the void 4Z may be from 5.0 nm to 30.0 nm. As a size of the void 4Z, the longest size of the void 4Z appearing in the cross section of the charge function layer 4 may be used. When the average size of the void 4Z is less than 5.0 nm, the organic molecules cannot sufficiently enter into the space where the inorganic hole transport material is not present, and the carrier-density improvement effect may be reduced. On the other hand, when the average size of the void 4Z is more than 30 nm, the space where the inorganic hole transport material is not present increases, and the carrier transport capability of the charge function layer 4 may be reduced.

The thickness of the organic film 4F may be from 0.5 nm to 2.0 nm. When the thickness of the organic film 4F (the size of the organic molecule T) is less than 0.5 nm, the bonding force of the organic molecule T to the inorganic hole transport material may be reduced. When the thickness of the organic film 4F (the size of the organic molecule T) is more than 2.0 nm, it may be difficult for the organic molecule T to enter into the space 4S having no inorganic hole transport material.

The inorganic hole transport material of the charge function layer 4 may be metal chalcogenide. The metal chalcogenide may be metal oxide or a metal compound including at least one of a CN group, SCN group, or SeCN group.

The second functional group K2 of the organic molecule T may have an electron-withdrawing property, and the metal chalcogenide serving as an inorganic hole transport material may include at least one of Ni, Cu, Fe, or Co. In this case, the inorganic hole transport material is a p-type semiconductor.

The second functional group K2 of the organic molecule T may have an electron-donating property, and the metal chalcogenide serving as an inorganic hole transport material may include at least one of Mo, V, or W. In this case, the inorganic hole transport material is an n-type semiconductor.

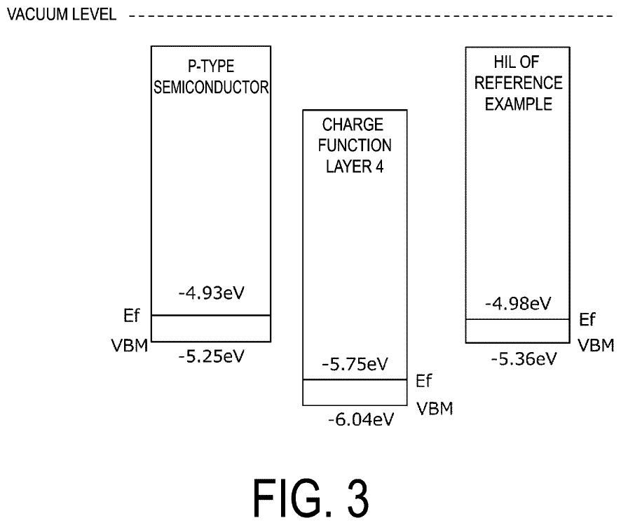

The inorganic hole transport material of the charge function layer 4 may be a p-type semiconductor. FIG. 3 is a band diagram of an inorganic hole transport material (p-type semiconductor) and a charge function layer. As illustrated in FIG. 3, a Fermi level (Ef) of the charge function layer 4 may be deeper than a Fermi level (Ef) of the p-type semiconductor (inorganic hole transport material), and a difference between a valence band maximum level (VBM) and the Fermi level (Ef) of the charge function layer 4 may be smaller than a difference between a valence band maximum level (VBM) and the Fermi level (Ef) of the p-type semiconductor. In this case, the hole transport function of the charge function layer 4 is enhanced, whereby the drive voltage of the light-emitting element 10 can be lowered. The valence band maximum level (VBM) of the charge function layer 4 may be deeper than the valence band maximum level (VBM) of the p-type semiconductor (inorganic hole transport material). In this case, an energy barrier between the charge function layer 4 and the hole transport layer 5 is reduced, whereby the drive voltage of the light-emitting element 10 can be further lowered. The p-type semiconductor serving as the inorganic hole transport material may be nickel oxide. In this case, nickel oxide is chemically stable, and stable characteristics are easily obtained. The charge function layer 4 in FIG. 3 contains an organic molecule including a second functional group having an electron-withdrawing property. A reference example in FIG. 3 is a case where an organic molecule not including a second functional group is used for HIL, and it is understood that the effect as exhibited in the charge function layer 4 is not observed in this case.

The inorganic hole transport material of the charge function layer 4 may be an n-type semiconductor. A difference between a conduction band minimum level (CBM) and the Fermi level (Ef) of the charge function layer 4 may be smaller than a difference between a conduction band minimum level (CBM) and a Fermi level (Ef) of the n-type semiconductor. In this case, the hole transport function of the charge function layer 4 is enhanced, whereby the drive voltage of the light-emitting element 10 can be lowered. The charge function layer 4 in this case contains an organic molecule including a second functional group having an electron-donating property.

As illustrated in FIG. 2, the charge function layer 4 may include a plurality of nanoparticles NP containing an inorganic hole transport material. In the charge function layer 4, by forming a nanoparticle layer including the plurality of nanoparticles NP as the inorganic layer 4U, the space 4S and the void 4Z are easily formed in the charge function layer 4.

The size of the nanoparticle NP may be from 4.0 nm to 9.0 nm. When the size of the nanoparticle NP is less than 4.0 nm, the electrical conductivity of the nanoparticle P may be lowered. On the other hand, when the size of the nanoparticle NP exceeds 9.0 nm, unevenness of the inorganic layer 4U becomes large to cause the charge function layer 4 to be in contact with the light-emitting layer 6 or the electron transport layer 7, and thus there is a possibility that the reactive current increases.

The sizes of the plurality of nanoparticles NP may satisfy a relation of 5.0 nm≤D50≤40 nm. When D50 is less than 5.0 nm, the electrical conductivity of the nanoparticles may be lowered. On the other hand, when D50 exceeds 40 nm, the unevenness of the inorganic layer 4U becomes large to cause the charge function layer 4 to be in contact with the light-emitting layer 6 or the electron transport layer 7, and thus there arises a possibility that the reactive current increases. D50 is a median size which means that the volume sum of nanoparticles with a particle size equal to or smaller than D50 is 50% of the volume sum of all nanoparticles. As the size of the nanoparticle NP, a diameter of a circular shape can be used; the circular shape is obtained by performing isovolumetric change on the nanoparticle NP appearing in the cross section of the charge function layer 4.

The sizes of the plurality of nanoparticles NP may satisfy a relation of 3.0 nm≤(D84−D16)/2≤10 nm. Here, (D84−D16) is referred to as a particle size deviation. When the particle size deviation (D84−D16) is less than 3.0 nm, the particle size distribution is narrow, making the inorganic layer 4U too dense, so that the porosity of the charge function layer 4 may decrease. On the other hand, when the particle size deviation is more than 10 nm, the particle size distribution is wide and coarse particles are also included, so that the porosity of the inorganic layer 4U becomes large, and the porosity of the charge function layer 4 may become too large.

In FIG. 2, each of the plurality of nanoparticles NP may be a nickel oxide nanoparticle. The organic molecule T may include one or two first functional groups K1. In this case, the first functional group K1 not being bonded to the inorganic layer 4U is likely to be present, which makes it possible to prevent the hole transport in the charge function layer 4 from being obstructed. The first functional group K1 may include a phosphoryl group. In this case, the inorganic hole transport material and the first functional group K1 are easily bonded to each other, and thus the charge function layer 4 can be easily formed.

As illustrated in FIG. 2, the inorganic hole transport material may be a p-type semiconductor, the inorganic layer 4U may be a nanoparticle layer of metal chalcogenide, the second functional group K2 of the organic molecule T may have an electron-withdrawing property, and the self-assembled monomolecule (SAM) of the same material as the organic molecule T may be included in each of the upper side and the lower side of an inorganic layer upper face 4J.

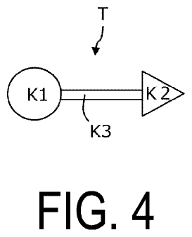

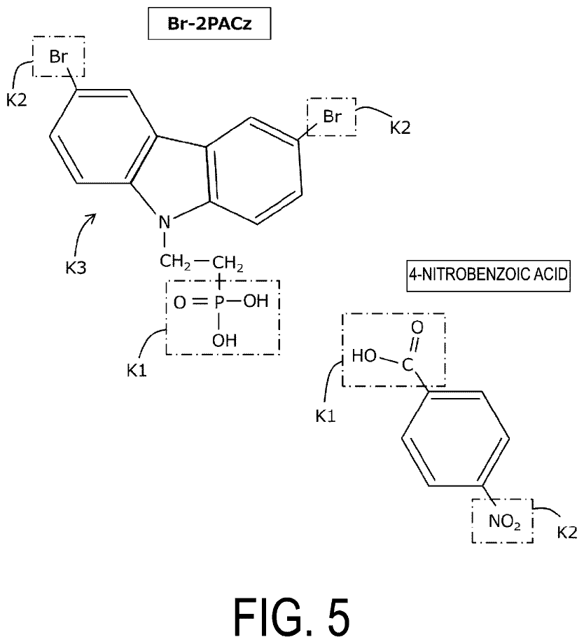

FIG. 4 is a schematic diagram illustrating an example of an organic molecule. FIG. 5 is a structural formula depicting an example of an organic molecule. As illustrated in FIG. 4, the organic molecule T may include a functional group K3 having a hole transport property (e.g., a carbazole group, a tetracyano group, a triarylamine group, a fluorene group, a quinonediimide group, a phthalocyanine group, a triphenylene group, and a phenylnaphthalene group). As illustrated in FIG. 5, the organic molecule T may be Br-2PACz ([2-(3,6-dibromo-9H-carbazole-9-yl)ethyl] phosphonic acid), or may be 4-nitrobenzoic acid. Other examples of the organic molecule T include a molecule in which Br of Br-2PACz is substituted with any one of F, Cl, and I as another halogen, 4-(trifluoromethyl)benzoic acid, and 4-chlorobenzoic acid.

In FIG. 2, the drive voltage of the light-emitting element 10 can be lowered by providing the organic molecule T in the void 4Z of the charge function layer 4. That is, by bonding the organic film 4F (self-assembled monomolecular film) including the second functional group K2 having an electron-withdrawing property to the inorganic hole transport material (e.g., nickel oxide) so as to deepen VBM (the valence band maximum level), the energy barrier between the charge function layer 4 and the hole transport layer 5 becomes small, and thus the drive voltage can be lowered.

It has been found that the difference between Ef (Fermi level) and VBM in the charge function layer 4 is reduced in this case. For example, when the organic molecule T has an electron-withdrawing property, the organic molecule T withdraws electrons of the inorganic hole transport material, and holes in the inorganic hole transport material increase, whereby the Fermi level approaches VBM, and the difference between Ef and VBM becomes small.

Then, by making the organic film 4F (self-assembled monomolecular film) adsorbed into the interior of the inorganic layer 4U, the carrier density and the mobility in the inorganic layer 4U were managed to be increased. Further, from experimental results, it has been found that the inorganic layer 4U exhibits a larger drive voltage reduction result by the organic film 4F (self-assembled monomolecular film) in a nanoparticle layer having a large number of voids (e.g., a nickel oxide nanoparticle layer) than in a sol-gel film having a small number of voids. Here, the sol-gel film is a film obtained by applying a precursor solution of an inorganic hole transport material and heating the applied precursor solution, whereby a dense film is likely to be formed. In this case, the precursor solution is a solution in which a salt containing nickel ions such as nickel acetate, nickel nitrate, or nickel chloride is dissolved in a solvent such as ethanol, dimethyl sulfoxide, or water in which the salt is dissolved, and a case where the solvent is water is referred to as a precursor aqueous solution.

In the light-emitting element 10, the charge function layer 4 may have a hole injection function, and the hole transport layer 5 including an organic material may be arranged between the charge function layer 4 and the light-emitting layer 6. When the hole transport layer 5 is included, the luminous efficiency of the light-emitting element 10 can be improved. The hole transport layer 5 may include a functional group (third functional group K3) having a hole transport property. In this case, holes are smoothly transported from the charge function layer 4 to the hole transport layer 5.

Examples of the material of the hole transport layer 5 include poly[(9,9-dioctylfluorenyl-2,7-diyl)-co-(4,4′-(N-(4-sec-butylphenyl))diphenylamine)] (abbreviated as “TFB”), poly[N,N′-bis(4-butylphenyl)-N,N′-bis(phenyl)-benzidine] (abbreviated as “poly-TPD”), polyvinyl carbazole (abbreviated as “PVK”), and poly[bis(4-phenyl)(2,4,6-trimethylphenyl)amine] (abbreviated as “PTAA”). One type of these materials may be used alone, or two or more types thereof may be mixed and used.

In the light-emitting layer 6, holes from the anode 3 recombine with electrons from the cathode 8 to emit light. The light-emitting element 10 may be configured to emit light in the light-emitting layer 6 by applying a voltage or a current between the anode 3 and the cathode 8. The light-emitting layer 6 may include the plurality of quantum dots Q each having a light emission property. The quantum dot Q refers to a dot (particle) having a maximum width of 100 nm or less. The shape of the quantum dot Q is not particularly limited as long as it is within a range satisfying the maximum width, and the shape is not limited to a spherical three-dimensional shape (circular cross-sectional shape). The shape of the quantum dot Q may be, for example, a polygonal cross-sectional shape, a rod-shaped three-dimensional shape, a branch-shaped three-dimensional shape, or a three-dimensional shape having unevenness on the surface thereof, or a combination of them. The quantum dot is typically a semiconductor single crystal, and may have a particle size of from 1.0 nm to 50 nm. The quantum dot may have a crystal of a group II-VI semiconductor compound such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, or HgTe, and/or a group III-V semiconductor compound such as GaAs, GaP, InN, InAs, InP, or InSb, and/or a group IV semiconductor compound such as Si or Ge. The quantum dot Q may be, for example, a core-shell type in which the above-described semiconductor crystal is used as a core and the core is overcoated with a shell material having a high band gap, or may be a shell-less type including only the core. The light-emitting layer 6 may include an organic ligand or an inorganic ligand on the surface of the quantum dot Q.

The light-emitting layer 6 may include an inorganic matrix material 6X, which fills spaces between the plurality of quantum dots Q each having a light emission property. The inorganic matrix material 6X refers to a member that includes and holds other objects, and can be rephrased as a base material, a parent material, or a filler. The inorganic matrix material 6X may be a constituent element of the light-emitting layer 6 including the plurality of quantum dots QD each having a light emission property. The light-emitting layer 6 may be filled with the inorganic matrix material 6X. The inorganic matrix material 6X may be an amorphous one. The elemental ratio of carbon in the inorganic matrix material 6X may be 10% or less.

It is desirable for the inorganic matrix material 6X to have a wider band gap than the core material of the quantum dot Q. As the inorganic matrix material 6X, a semiconductor or an insulator can be used. The inorganic matrix material 6X may contain at least one of metal sulfide and metal oxide. Examples of the metal sulfide may include zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), and magnesium gallium sulfide (MgGa₂S₄). Examples of the metal oxide may include zinc oxide (ZnO), titanium oxide (TiO₂), tin oxide (SnO₂), tungsten oxide (WO₃), zirconium oxide (ZrO₂), and silicon oxide (SiO₂).

The anode 3 supplies holes to the light-emitting layer 6. The cathode 8 supplies electrons to the light-emitting layer 6. The cathode 8 may be positioned so as to face the anode 3. In FIG. 1, the cathode 8 is positioned above the anode 3.

At least one of the anode 3 and the cathode 8 may be formed of a light-transmissive material. A transparent conductive material can be used as the light-transmissive material, for example. As the transparent conductive material, for example, indium tin oxide (ITO), indium zinc oxide (IZO), tin oxide (SnO₂), or fluorine-doped tin oxide (FTO) can be used. Since these materials have high transmittance of visible light, the luminous efficiency of the light-emitting element 10 is improved.

At least one of the anode 3 and the cathode 8 may be formed of a light-reflective material. A metal material can be used as the light-reflective material, for example. As the metal material, for example, aluminum (Al), silver (Ag), copper (Cu), gold (Au), or the like can be used. Since these materials have high reflectivity of visible light, the luminous efficiency of the light-emitting element 10 is improved.

The electron transport layer 7 is located between the light-emitting layer 6 and the cathode 8. The electron transport layer 7 transports electrons from the cathode 8 to the light-emitting layer 6. Examples of the material of the electron transport layer 7 include zinc oxide (ZnO), zinc magnesium oxide (MgZnO), titanium oxide (TiO₂), and strontium oxide (SrTiO₃). These materials may be nanoparticles. As described above, the electron transport layer 7 may include MgZnO. In this case, injection of electrons is suppressed, the carrier balance of the light-emitting element 10 is easily adjusted, and the luminous efficiency is improved.

Other examples of the material of the electron transport layer 7 include compounds or complexes containing one or more nitrogen-including hetero rings such as an oxadiazole ring, a triazole ring, a triazine ring, a quinoline ring, a phenanthroline ring, a pyrimidine ring, a pyridine ring, an imidazole ring, and a carbazole ring.

Further examples of the material of the electron transport layer 7 include 1,10-phenanthroline derivatives such as bathocuproine and bathophenanthroline, benzimidazole derivatives such as 1,3,5-tris (N-phenylbenzimidazole-2-yl)benzene (TPBI), bis (10-benzoquinolinolato) beryllium complexes, 8-hydroxyquinoline Al complexes, metal complexes such as bis (2-methyl-8-quinolinate)-4-phenylphenolate aluminum, and 4,4′-biscarbazole biphenyl. Other examples include aromatic boron compounds, aromatic silane compounds, aromatic phosphine compounds such as phenyldi (1-pyrenyl) phosphine, and nitrogen-containing heterocyclic compounds such as bathophenanthroline, bathocuproine, and triazine derivatives. One type of these materials may be used alone, or two or more types thereof may be mixed and used.

For the charge function layer 4, a cross-sectional image of the light-emitting element 10 is obtained by scanning electron microscopy (SEM), and then the porosity can be calculated from the contrast of the cross-sectional image. As a method of extracting the charge function layer 4 from the cross-sectional image, a visual determination by a human may be a primary approach, a determination by a computer or artificial intelligence (AI) may be a secondary approach, and a determination by a human assisted by a computer or AI may be a tertiary approach. Specifically, a line passing through between the pixels where the luminance distribution of the pixels changes most steeply is extracted as a contour line candidate of the charge function layer 4. Subsequently, a boundary of the void 4Z is extracted from the charge function layer 4 by contrast determination. Specifically, a histogram of the luminance is created for all pixels, a threshold value is determined by, for example, a maximum entropy method, and pixels included in a region equal to or greater than the threshold value are whitened. On the other hand, the other pixels included in the region in the charge function layer 4 are blackened. Subsequently, the numbers of white pixels and black pixels included in the region in the charge function layer 4 are counted, and the porosity is calculated. In this case, an equation of porosity=the number of white pixels/(the number of white pixels+the number of black pixels) is used. When it is difficult to determine the threshold value by the above-described method, the threshold value may be determined by, for example, a percentile method. The void size (pore size) can be determined by measuring, for example, the longest size of the void 4Z from the cross-sectional image.

Furthermore, when elemental analysis is performed on the cross section of the charge function layer 4 by combining SEM and energy dispersive X-ray spectroscopy (EDX), the inorganic hole transport material can be identified. In this case, the cross section of the light-emitting element is obtained by focused ion beam (FIB) processing.

The organic molecule T can be identified by performing etching until reaching the charge function layer 4 by gas cluster ion beam (GCIB), and by analysis using time-of-flight secondary ion mass spectrometry (TOF-SIMS) of the charge function layer 4 and tandem mass spectrometry (MS/MS).

### Example 1 and Example 2

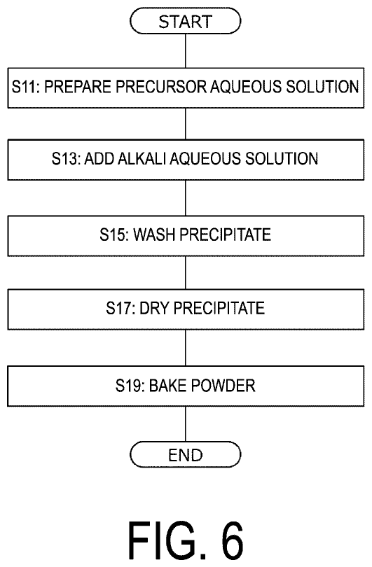

FIG. 6 is a flowchart illustrating an example of a method for manufacturing nanoparticles. As illustrated in FIG. 6, in step S11, 0.05 mmol of nickel nitrate hexahydrate (Ni(NO₃)₂·6H₂O) and 20 mL of pure water are mixed and stirred to prepare a precursor aqueous solution. In step S13, 10 mol/L of a sodium hydroxide aqueous solution is added to the precursor aqueous solution until the pH reaches 9 to 11 (e.g., pH 10) at a rate of 0.4 to 0.5 mg/min (e.g., 0.45 mg/min) so as to obtain a green precipitate. In step S15, a washing process in which pure water is added to the green precipitate, the mixture is centrifuged, and the supernatant is removed is repeated three times. In step S17, the washed green precipitate is dried at 60 to 100° C. (e.g., 80° C.) to obtain green powder. In step S19, the green powder is baked at 250 to 300° C. for two to six hours (e.g., 270° C. for two hours) to obtain powder of black nickel oxide nanoparticles.

The particle size of the nanoparticle can be measured, for example, as follows. The nickel oxide nanoparticles were dispersed in an aqueous solvent, and a solution having passed through a filter with a pore size of 0.45 μm was subjected to particle size distribution measurement using a particle size distribution measuring device (Nanotrac waveII, manufactured by MicrotracBEL Corp.), and the obtained result was defined as the particle size. Further, the median size D50 (nm) of the nanoparticles was calculated therefrom. The particle size in the present example was from 6.4 to 86 nm, and the D50 was 9.9 nm. The particle size deviation (D84-D16) in the example was 4.5 nm.

The nickel oxide nanoparticles prepared by the method described above contain nitrate ions and have high dispersibility in water. When the addition rate of the sodium hydroxide aqueous solution is out of the above-mentioned range, the particles having a particle size of 100 nm or more are present, and the unevenness of the inorganic layer 4U becomes large, so that the charge function layer 4 and the light-emitting layer 6 or the electron transport layer 7 come into contact with each other, and there arises a possibility that the reactive current increases.

The size of a crystallite of the nanoparticles can be measured, for example, as follows. X-ray intensity with respect to a diffraction angle 20 was measured for the nickel oxide nanoparticles by using a powder X-ray diffraction (XRD) device (MiniFlexII, manufactured by Rigaku Corporation), and a crystallite size d (nm) was calculated from the measurement result using the following Scherrer equation.

d=0.89λ/B cos θ

Note that λ (nm) is a wavelength of the X-ray, and in the present measurement, CuKα radiation having a wavelength of λ=0.154 (nm) was used. B is a full width at half maximum (FWHM) of the X-ray diffraction peak. The crystallite size d in the example was 4.3 nm.

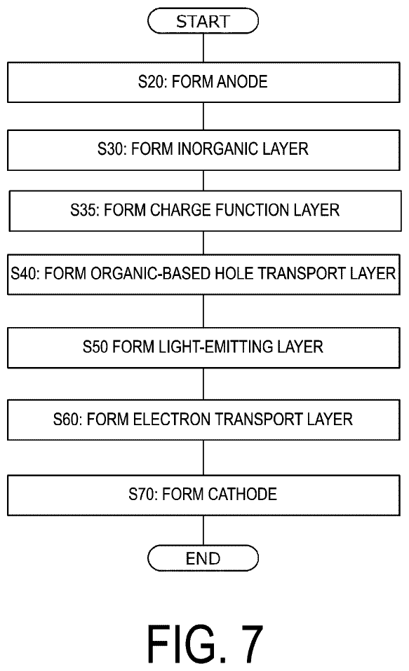

FIG. 7 is a flowchart illustrating an example of a method for manufacturing a light-emitting element. As illustrated in FIG. 7, in step S20, an anode is formed by forming a film of ITO (film thickness 30 nm, 2 mm×10 mm) on a substrate by sputtering. In step S30, 0.1 ml of a nanoparticle dispersion in which 30 mg of the nickel oxide nanoparticles prepared in FIG. 6 is dispersed in 1.0 ml of water and 1.0 ml of 2-methoxyethanol is spin-coated on the anode (ITO) and then dried at 200° C., and the same processing (spin coating and drying) is repeated several times to form an inorganic layer. The film thickness of the inorganic layer was 50 nm.

In step S35, a solution in which Br-2PACz is dissolved in ethanol so as to be 0.01 M (mol/l) is brought into contact with the inorganic layer for five seconds or more, and then dried to form a charge function layer. In step S35, the charge function layer may be formed as follows: in a solution in which 4-nitrobenzoic acid is dissolved in methanol to be 0.1 M, an inorganic layer is immersed for one hour and then dried.

In step S40, 8 mg of TFB was dissolved in 1 ml of chlorobenzene, and the mixture was applied on the charge function layer by spin coating to form an organic-based hole transport layer. The film thickness of the organic-based hole transport layer was 40 nm. In step S50, 0.05 to 0.1 ml of a quantum dot solution containing InP/ZnS (core/shell) or CdSe/ZnS (core/shell) was applied on the organic-based hole transport layer by a spin coating method to form a light-emitting layer. In step S60, an electron transport layer was formed by applying a nanoparticle dispersion of MgZnO or ZnO on the light-emitting layer by the spin coating method. The thickness of the electron transport layer was 60 nm. In step S70, a cathode was formed by vapor-depositing an electrode of Ag or Al on the electron transport layer by vacuum vapor deposition. The thickness of the cathode was 50 nm.

A case where the inorganic layer (nanoparticle layer) is formed in step S30 described above is defined as Example 1; a case where, in place of step S30 described above, 0.1 ml of a liquid in which 0.248 g of nickel acetate tetrahydrate is dissolved in 5 ml of ethanol is spin-coated on ITO (the anode), and the spin-coated liquid is dried at 230° C. to form the inorganic layer (sol-gel layer) is defined as Example 2.

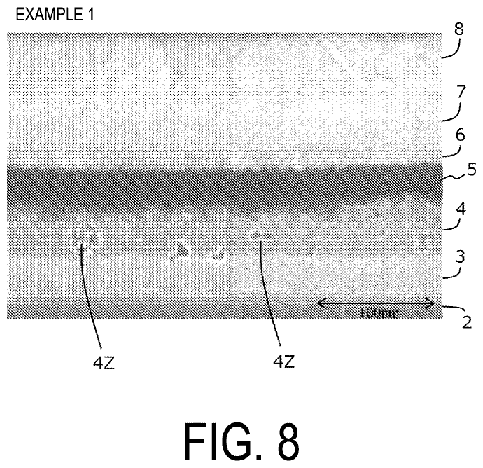

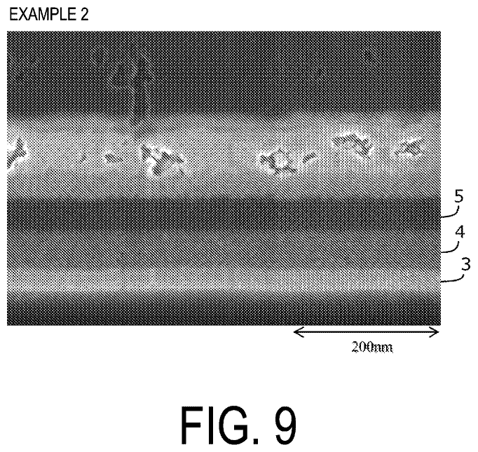

FIG. 8 is a cross-sectional SEM image of a light-emitting element according to Example 1. FIG. 9 is a cross-sectional SEM image of a light-emitting element according to Example 2. In this case, the porosity of the charge function layer (Example 1) in FIG. 8 was 3.2%, and the porosity of the charge function layer (Example 2) in FIG. 9 was 2.7%.

The light-emitting element can be evaluated, for example, as follows. An application voltage V (voltage between the cathode and the anode) was applied to each of the light-emitting elements using a spectrum measuring device (MCPD7000, manufactured by Otsuka Electronics Co., Ltd.) and a current-voltage characteristic measuring device (2400, manufactured by Keithley Instruments, Inc.), and a luminance value L of light emitted from each light-emitting element was measured using a luminance spectrum measuring device (spectrometer). Further, V-J characteristics were measured by changing the applied voltage V in various ways.

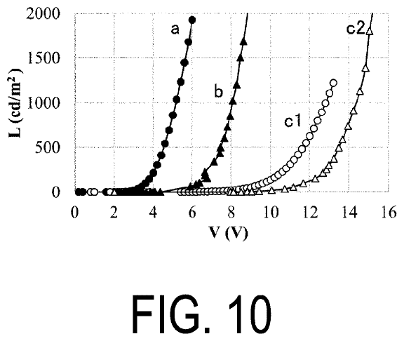

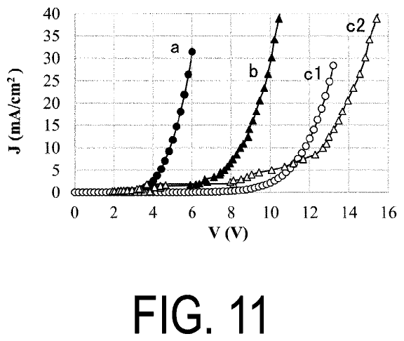

FIG. 10 is a graph depicting voltage (V)-luminance (L) characteristics of light-emitting elements according to Example 1, Example 2, Comparative Example 1, and Comparative Example 2. FIG. 11 is a graph depicting voltage (V)-current density (J) characteristics of light-emitting elements according to Example 1, Example 2, Comparative Example 1, and Comparative Example 2. Comparative Example 1 is a case where only a nickel oxide nanoparticle layer (with no organic molecule) was formed as HIL, and Comparative Example 2 is a case where only a nickel oxide sol-gel layer (with no organic molecule) was formed as HIL. It is understood from FIG. 10 that the voltage-luminance characteristics are improved in Example 1 (graph a) as compared with Comparative Example 1 (graph c1). Specifically, in Example 1, the voltage required for luminance 1000 cd/m² is reduced by about 7.6 V compared to Comparative Example 1 including no organic molecule. In Example 2 (graph b), the voltage required for luminance 1000 cd/m² is reduced by about 6.3 V compared to Comparative Example 2 (graph c2) including no organic molecule.

It is understood from FIG. 11 that the voltage-current density characteristics are improved in Example 1 (graph a) as compared with Comparative Example 1 (graph c1). Specifically, in Example 1, the voltage required for flowing 10 mA/cm² is reduced by about 7 V compared to Comparative Example 1 including no organic molecule. In Example 2 (graph b), the voltage required for flowing a current of 10 mA/cm² is reduced by about 4 V compared to Comparative Example 2 (graph c2) including no organic molecule.

It is also understood from FIGS. 10 and 11 that the voltage-current density characteristics of Example 1 is superior to those of Example 2. This is because in Example 1, organic molecules including an electron-withdrawing functional group entered into the inorganic layer through the voids and were adsorbed on the surface of the inorganic hole transport material, thereby improving the carrier density of the inorganic hole transport material and increasing the mobility of the charge function layer.

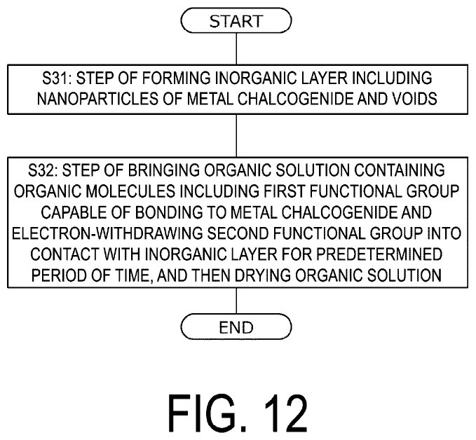

FIG. 12 is a flowchart illustrating an example of a method for manufacturing a light-emitting element. In FIG. 12, a process of forming an inorganic layer (nanoparticle layer) including nanoparticles of metal chalcogenide and voids is carried out in step S31, and in step S32, a process of bringing an organic solution containing organic molecules including a first functional group capable of bonding to the metal chalcogenide and an electron-withdrawing second functional group into contact with the inorganic layer (nanoparticle layer) for a predetermined period of time, and then drying the organic solution. With this, the charge function layer of Example 1 can be formed.

### Example 3

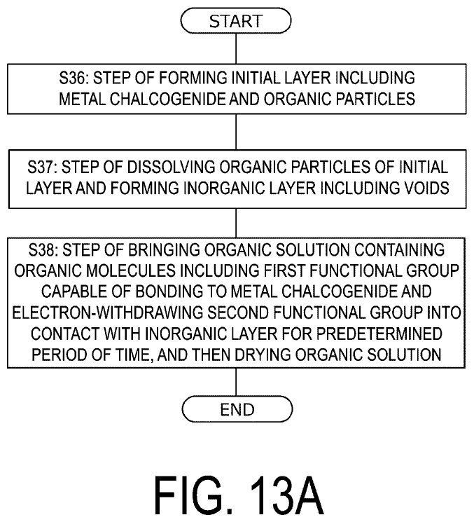

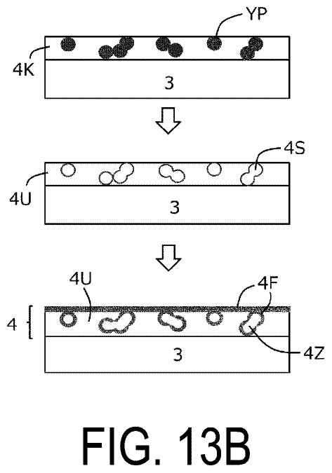

FIG. 13A is a flowchart illustrating an example of a method for manufacturing a light-emitting element. FIG. 13B is a cross-sectional view illustrating an example of a method for manufacturing a light-emitting element. As illustrated in FIG. 13A and FIG. 13B, in step S36, an initial layer 4K including metal chalcogenide and organic particles is formed. To be specific, 0.1 ml of a solution in which 0.248 g of nickel acetate tetrahydrate is dissolved in 5 ml of ethanol, and polystyrene nanoparticles (organic particles) YP having a particle size of 20 nm are added in an amount of 7 mg is spin-coated on ITO (the anode), and dried at 110° C. to form the initial layer 4K.

In step S37, the organic particles YP of the initial layer 4K are dissolved to form the inorganic layer 4U including the space 4S. Specifically, the initial layer is immersed in toluene to dissolve the polystyrene nanoparticles YP, and dried at 230° C. The inorganic layer 4U including the void 4S can be formed by the dissolution of the polystyrene nanoparticles YP.

In step S38, an organic solution containing organic molecules including a first functional group capable of bonding to the metal chalcogenide and an electron-withdrawing second functional group is brought into contact with the inorganic layer for a predetermined period of time, and then the organic solution is dried. Specifically, the inorganic layer is immersed for one hour in a solution in which 4-nitrobenzoic acid is dissolved in ethanol to be 0.01 mol/l, and thereafter the organic solution is dried, thereby forming the charge function layer 4 including the void 4Z and the organic film (self-assembled monomolecular film) 4F. The thickness of the charge function layer 4 was 45 nm.

In Example 3, the charge function layer 4 having a porosity of 5% can be obtained. It has been found that the light-emitting element including the charge function layer obtained in step S38 reduces power consumption required for obtaining the same luminance as compared with Example 2 and Comparative Examples 1 and 2.

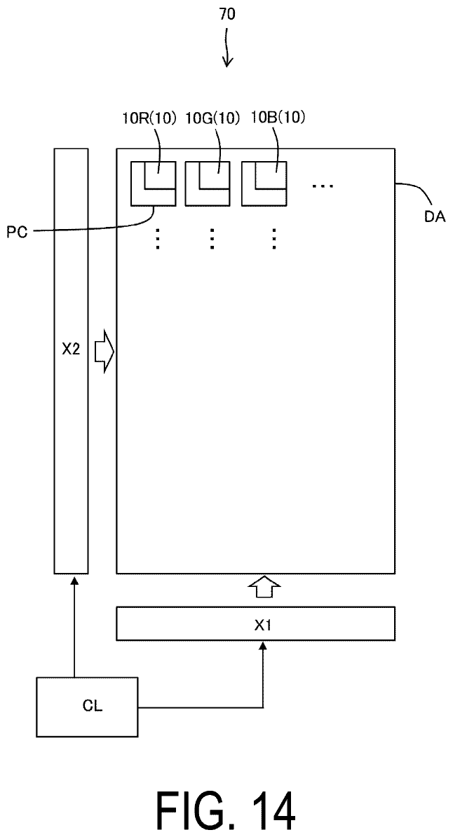

FIG. 14 is a schematic diagram illustrating a configuration example of a display device according to the present embodiment. A display device 70 includes a display unit DA, a first driver circuit X1 (e.g., a data signal line drive circuit) and a second driver circuit X2 (e.g., a scanning signal line drive circuit and a light emission control line drive circuit) that drive the display unit DA, and a control circuit CL that controls the first driver circuit X1 and the second driver circuit X2. The display unit DA may include a pixel circuit layer and a light-emitting element layer. The light-emitting element layer may include a light-emitting element 10R (10) that emits red light, a light-emitting element 10G (10) that emits green light, and a light-emitting element 10B (10) that emits blue light, and each of the light-emitting elements 10R, 10G, and 10B may be connected to a pixel circuit PC formed in the pixel circuit layer.

### APPENDIX

The embodiments described above are for the purpose of illustration and description and are not intended to be limiting. It will be apparent to those skilled in the art that many variations will be possible in accordance with these examples and descriptions.

1. A light-emitting element comprising:
an anode and a cathode;
a light-emitting layer located between the anode and the cathode; and
a charge function layer located between the anode and the light-emitting layer,
wherein the charge function layer includes an inorganic layer including an inorganic hole transport material, at least one void, and an organic molecule,
the organic molecule includes a first functional group capable of bonding to the inorganic hole transport material, and a second functional group having an electron-withdrawing property or an electron-donating property, and
the light-emitting layer includes a plurality of quantum dots each having a light emission property, and an inorganic matrix material filling a portion between the plurality of quantum dots.

2. A light-emitting element comprising:
an anode and a cathode;
a light-emitting layer located between the anode and the cathode; and
a charge function layer located between the anode and the light-emitting layer,
wherein the charge function layer includes an inorganic layer including metal chalcogenide serving as an inorganic hole transport material, at least one void, and an organic molecule,
the organic molecule includes a first functional group including at least one of a carboxyl group, a silanol group, a phosphoryl group, a thiol group, or an amino group, and a second functional group including at least one of a nitro group, a halogen group, an amino group, a methoxy group, or an ethoxy group, and
the light-emitting layer includes a plurality of quantum dots each having a light emission property, and an inorganic matrix material filling a portion between the plurality of quantum dots.

3. The light-emitting element according to claim 1,
wherein the void is located inside the inorganic layer.

4. The light-emitting element according to claim 1,
wherein the organic molecule is in contact with the void.

5. The light-emitting element according to claim 1,
wherein the organic molecule is a self-assembled monomolecule, and
an organic film including the self-assembled monomolecule is arranged in the void.

6. The light-emitting element according to claim 5,
wherein the organic film is located around the void.

7. (canceled)

8. The light-emitting element according to claim 1,
wherein the second functional group includes at least one of a nitro group, a halogen group, an amino group, a methoxy group, or an ethoxy group.

9. The light-emitting element according to claim 1,
wherein a porosity in the charge function layer is from 3.0% to 15.0%.

10. The light-emitting element according to claim 1,
wherein an average size of the void is from 5.0 nm to 30.0 nm.

11. The light-emitting element according to claim 5,
wherein a thickness of the organic film is from 0.5 nm to 2.0 nm.

12. (canceled)

13. (canceled)

14. (canceled)

15. (canceled)

16. (canceled)

17. (canceled)

18. (canceled)

19. (canceled)

20. The light-emitting element according to claim 1,
wherein the inorganic layer includes a plurality of nanoparticles including the inorganic hole transport material.

21. The light-emitting element according to claim 20,
wherein sizes of the plurality of nanoparticles satisfy a relation of 5.0 nm≤D50≤40 nm.

22. The light-emitting element according to claim 20,
wherein sizes of the plurality of nanoparticles satisfy a relation of 3.0 nm≤(D84−D16)/2≤10 nm.

23. The light-emitting element according to claim 20,
wherein each of the plurality of nanoparticles is a nickel oxide nanoparticle.

24. The light-emitting element according to claim 1,
wherein the organic molecule includes one or two of the first functional groups.

25. The light-emitting element according to claim 1,
wherein the first functional group includes a phosphoryl group.

26. (canceled)

27. The light-emitting element according to claim 22,
wherein the organic molecule is Br-2PACz.

28. The light-emitting element according to claim 27,
wherein the charge function layer further includes a hole injection function, and
a hole transport layer including an organic material is provided between the charge function layer and the light-emitting layer.

29. (canceled)

30. The light-emitting element according to claim 1,
wherein the inorganic hole transport material is a p-type semiconductor,
the inorganic layer is a nanoparticle layer of metal chalcogenide,
the second functional group of the organic molecule has an electron-withdrawing property, and
a self-assembled monomolecule of a material identical to the material of the organic molecule is included in each of an upper side and a lower side of an upper face of the inorganic layer.

31. A display device comprising:
the light-emitting element according to claim 1.

32. (canceled)

33. (canceled)

34. (canceled)
